(19) United States
(12) Patent Application Publication
(10) Pub. No.: US 2017/0333806 A1
(43) Pub. Date: Nov. 23, 2017

(54) SYSTEM AND METHOD FOR EVAPORATING A METAL

(71) Applicant: General Fusion Inc., Burnaby (CA)

(72) Inventors: Alexander Douglas Mossman, Vancouver (CA); David Franklin Plant, Vancouver (CA)

(73) Assignee: General Fusion Inc., Burnaby (BC)

(21) Appl. No.: 15/522,460

(22) PCT Filed: Nov. 2, 2015
(86) PCT No.: PCT/CA2015/051121

§ 371 Date: Apr. 27, 2017

Related U.S. Application Data
(60) Provisional application No. 62/074,758, filed on Nov. 4, 2014.

(51) Int. Cl. B01D 1/00; C23C 14/06; C23C 14/24; B01J 3/03

(52) U.S. Cl. CPC B01D 1/0017; C23C 14/24; B01D 1/0082; C23C 14/06; B01J 3/03

(57) ABSTRACT

Examples of a device for gettering and surface conditioning are disclosed. The device comprises an elongated tube with a closed first end, a second end and a body extending between the first end and the second end. The body defines an inner cavity of the tube in which a heating device is inserted. The tube is inserted into a vessel so that the first end is positioned within the vessel. A solid metal is mounted closely to the tube in a region surrounding the heating device and a meshed screen is mounted over the solid metal and secured to the tube. When the heating device is on, the heat transfers through the tube's wall into the solid metal melting and vaporizing it, so that the metal vapors travel and coat onto vessel's surfaces. The device can also be used in producing metal alloys such as lead lithium alloys.

### CROSS-REFERENCE TO RELATED APPLICATIONS

The present application is a U.S. National Phase of international application no. PCT/CA2015/051121, filed Nov. 2, 2015, entitled SYSTEM AND METHOD FOR EVAPORATING A METAL, which claims priority to U.S. Application No. 62/074,758, filed Nov. 4, 2014; all of the foregoing are hereby incorporated by reference herein in their entireties for all that they disclose.

### TECHNICAL FIELD

The present disclosure relates generally to a system and method for evaporating a metal in a vacuum.

### BACKGROUND

Unless otherwise indicated herein, the materials described in this section are not prior art to the claims in this application and are not admitted to be prior art by inclusion in this section.

Systems for evaporating metal on inner surfaces of a vacuum vessel can be used in the field of plasma physics or ultrahigh vacuum, for example for chemical gettering and surface conditioning of a plasma confinement vessel. The term “gettering” used herein means depositing a reactive material (gettering material) on the inner surface of a vacuum system, for the purpose of completing and maintaining the vacuum. The inner surfaces of the vacuum vessel can continue releasing gases adsorbed therein even after the vacuum has been established. The gettering material combines with such gases either chemically or by absorption and thus continues removing the residual gases as they are produced. The getter is usually a coating applied to a surface within the evacuated vacuum vessel.

In plasma confinement systems, gas particles entering the plasma will radiate energy, cooling the plasma and thus limiting its lifetime and temperature. A rate of energy radiation is proportional to the square of an atomic number of the contaminant so the gas with lower atomic number will radiate less energy. Due to the extreme conditions of hot and dense plasmas, any plasma facing wall will inevitably vaporize and contaminate the plasma. This being the case, lithium as an element with very low atomic number of 3 will produce a lower level of radiation, and is thus the most preferable and most benign plasma facing material. In addition, lithium is a strong getter meaning that it will react and bind with different gas species which may be present as contaminants in a vacuum vessel, such as for example, hydrogen to form lithium hydride, oxygen to form lithium oxide, nitrogen to form lithium nitride, water vapor to form lithium hydroxide, etc. Another cooling mechanism during plasma formation and confinement occurs when hot ions from the plasma escape and impact the plasma facing walls, cooling down and/or neutralizing. The cold ions or neutrals can then re-enter into the plasma and cool the plasma. This process is known as wall recycling. A lithium coated wall binds and retains the ions impacting on the wall, thus preventing re-entrance of these particles back into plasma.

A variety of wall conditioning techniques have been developed to achieve reduced wall recycling and impurities control in ultrahigh vacuum systems e.g. a plasma confinement systems. One exemplary wall conditioning technique uses stationary or movable evaporators which include one or more containers filled with metal that are introduced into the vacuum chamber and are heated to allow the metal to evaporate and coat the surrounding surfaces. However, the liquid metal in such evaporators can spill or drip during operation due to the free surface of the metal. In order to achieve uniform coating, the vacuum vessel should be first filled with an inert gas, so that the metal vapor (e.g. lithium vapor) is in a collisional regime to diffuse to all exposed surfaces in the vessel. However, such inert gas can be a source of additional contaminants.

Other wall conditioning techniques include installing metal targets into the vacuum vessel and heating such targets with lasers, electron beams, microwaves; or providing metal nanopowder into the vacuum vessels and timing the plasma formation, so that the plasma melts, entrains, and deposits the metal onto the vessel walls.

The known techniques for coating of plasma facing components have limitations such as, spilling/dripping, provide coating over vessel's diagnostics windows and insulators, failure to provide uniform and thin layer on all plasma facing surfaces (the thickness of the metal layer is determined/influenced by the vessel geometry), complex evaporation control, complex geometries, etc. In addition most of such systems and techniques are expensive, cumbersome and time consuming.

### SUMMARY

In one aspect, a device for evaporating a select metal in a vacuum vessel is provided. The device comprises a tube with a closed first end, a second end and a body extending between the first end and the second end. The body has a wall defining an inner cavity of the tube. A heating device that comprises a heater is positioned into the inner cavity of the tube. The heater is in thermal communication with the wall of the tube. A meshed screen mounted on an outside surface of the tube is provided. The meshed screen defines a basket into which the select metal is positioned so that it is in thermal communication with the wall of the tube. The meshed screen has a screen aperture size sufficient to contain the select metal when in liquid and solid phases and to pass the select metal when in vapor phase. The heater output, tube wall thermal conductivity, and heater and metal positions are selected such that heat from the heater is sufficient to liquefy and then vaporize the select metal.

The device further comprises a vessel seal surrounding the tube body configured to sealably connect the device to a vacuum vessel. The first end of the tube and the meshed screen are positionable inside the vessel. The heater is operable to liquefy and then vaporize the select metal inside the vessel such that the select metal coats inner surfaces of the vessel in line of sight with the meshed screen. The vessel seal further comprises means for moving the device within the vessel while maintaining a vacuum seal.

The heating device further comprises a sensor for measuring temperature of the heater and a controller in communication with the sensor and programmed to control the temperature of the heater at a pre-determined target temperature for a pre-determined coating time. The device further comprises cooling means in thermal communication with the heater configured to trigger the cooling means to cool the heater.

In one aspect, the solid metal comprises a plurality of metal chips.

In another aspect, the device comprises a sleeve that envelops the tube. The sleeve comprises an opened first end and a second end. The second end is connected to the meshed screen.

In yet another aspect, a method for evaporating a solid phase select metal in a vacuum is provided. The method comprises steps of placing the solid phase select metal in a basket defined by a mesh screen mounted to an outside surface of a tube, and positioning the select metal in a vacuum and in thermal communication with a heater positioned inside the tube. The mesh screen has an aperture size selected to contain the select metal when in solid and liquid phases, and to pass the select metal when in vapor phase. The method further comprises a step of operating the heater to generate a selected thermal output sufficient to liquefy and then vaporize the select metal such that a vapor phase of the select metal passes through the mesh screen.

The method further comprises steps of placing the tube, mesh screen basket and solid phase select metal inside a vacuum vessel, and establishing a vacuum inside the vessel such that the vapor phase select material passing through the mesh screen will coat inner surfaces of the vacuum vessel that are in line of sight of the mesh screen basket.

In one aspect, the method further comprises steps of adjusting a position of the device at a pre-determined depth and orientation in the vessel; turning on a power source electrically connected to the heater and setting a temperature of the heater to a pre-determined target temperature and maintaining the temperature of the heater at such target temperature for a duration of a pre-determined coating period, the target temperature being higher than an evaporation point of the select metal; melting the select metal into the meshed screen to wet the screen; and dispersing vapors of the select metal on inner walls of the cavity that are in a line-of-sight of the meshed screen.

In yet another aspect, the method further comprises steps of liquefying a second metal and contacting the vapor phase select metal with the liquefied second metal such that the select metal and second metal are mixed and a metal alloy is formed. The select metal is lithium and the second metal is a molten lead.

In addition to the aspects and embodiments described above, further aspects and embodiments will become apparent by reference to the drawings and study of the following detailed description.

### BRIEF DESCRIPTION OF THE DRAWINGS

Throughout the drawings, reference numbers may be re-used to indicate correspondence between referenced elements. The drawings are provided to illustrate example embodiments described herein and are not intended to limit the scope of the disclosure. Sizes and relative positions of elements in the drawings are not necessarily drawn to scale. For example, the shapes of various elements and angles are not drawn to scale, and some of these elements are arbitrarily enlarged and positioned to improve drawing legibility.

FIG. 1 is a cross-sectional side view of an embodiment of a device for metal evaporation in a vacuum vessel;

FIG. 2 is a graph illustrating a lithium coating in μm at various temperatures in ° C. obtained for a 10 minute coating run;

FIG. 3 illustrates photos of a device for producing a controlled metal evaporation and coating, before the start of a coating operation (photo on the left) and after a 10 minute coating period (photo on the right);

FIG. 4 is a cross-sectional side view of another embodiment of a device for metal evaporation in a vacuum vessel.

### DETAILED DESCRIPTION OF SPECIFIC EMBODIMENTS

The embodiments described herein relate generally to a system and method for evaporating a metal in a vacuum; this system and method can be used for producing a controlled metal coating on an inside surface of a vessel, or for other purposes such as forming a metal alloy, for example lead-lithium alloys. When coating a vessel, the method can be carried out to coat features that are in line of sight of a metal evaporation source, so that the vessel's features that are not in line of sight, such as instrumentation windows and insulators are not coated.

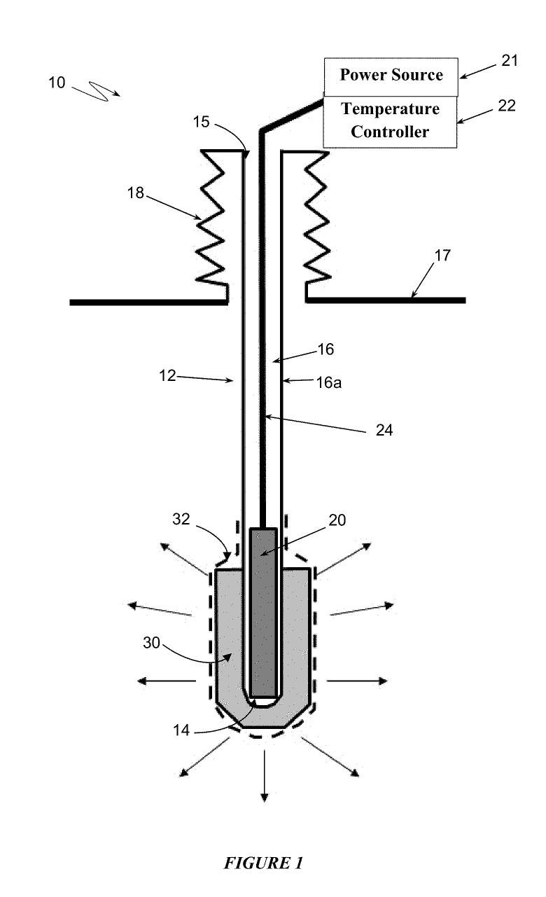

FIG. 1 shows an example of a device 10 configured to provide an evaporated metal dispersed uniformly in a vacuum vessel that can coat the inner surfaces of such vessel. The device 10 comprises an elongated tube 12 with a first end 14, a second end 15 and a body 16 extending between the first end 14 and the second end 15. The body 16 has a wall 16a defining an inner cavity of the tube 12. The first end 14 of the tube 12 is closed. The second end 15 can be partially closed. The tube 12 can be made of a stainless steel or any other suitable material and can have a variety of geometries, shapes and sizes depending on the size and geometry of a coating surface, and depending on thermal requirements as will be discussed further below. For example, the tube 12 can be a stainless steel tube with about ˜1 cm diameter, ˜20 cm length and thickness of the wall 16a of about ˜0.5 mm. This is for illustration purposes only and person skilled in the art would understand that the tube 12 can be made of different materials and can have other dimensions and/or shapes without departing from the scope of invention.

The tube 12 is inserted into a vacuum vessel (only wall 17 of the vessel is shown in FIG. 1) so that its first end 14 is well within an inner cavity of the vessel while the second end 15 of the tube 12 is outside the vessel. The device 10 is secured to the vessel wall 17 using a vacuum flange (not shown). A bellows 18, or a seal (not shown) suitable for sliding applications or any other suitable means for re-positioning can be provided to adjust the position of the tube 12 within the vessel by raising it or lowering it to the desired position/depth within the vessel while maintaining the vacuum conditions. The bellows 18 are positioned outside the vacuum vessel and are in communication with the second end 15 of the tube 12.

A heating device 20 is inserted into the tube 12 and is nested within the tube 12 in proximity to its first end 14. The heating device 20 can be a cartridge heater or any other suitable heating device. The industrial cartridge heater is inexpensive, simple, and robust and does not require ceramic vacuum feedthroughs thus reducing the cost of the device 10 and also improves its reliability. The heating device 20 is sized so that it can tightly fit within the inner cavity of the tube 12. A diameter of the heating device 20 can be slightly smaller than the inner diameter of the tube 12 so that the heating device 20 is closely fitted within the tube 12. The heating device 20 can further comprise a temperature measuring device, such as a thermocouple probe (not shown). The thermocouple can be separate or integral with the heating device 20. The heating device 20 can be connected to a power source 21 and a temperature controller 22, using for example power and thermocouple leads 24. For example the temperature controller can be a proportional-integral-derivative controller (PID controller).

A piece of solid metal 30 (i.e. a solid lithium metal) is mounted to the first end 14 of the tube 12. For example, the metal piece 30 can be placed over the tip (first end 14) of the tube 12 in a region from which evaporation is expected/desired (region around the heating device 20). For example, if the heating device 20 is positioned at some distance away from the first end 14 (towards a middle section of the tube 12) the metal piece 30 would be fitted around the wall 16a in the region surrounding the heating device 20. Heat is transferred into the solid metal 30 by conduction through the wall 16a of the tube 12. The wall 16a of the tube 12 can be selected with a material composition and a thickness that provides sufficient thermal conductivity to conduct heat produced by heater, such that the heat can melt and then vaporize the solid metal 30. In particular, the wall when made of stainless steel can be relatively thin to foster better heat transfer. The metal piece 30 can be formed by a variety of means, such as a hand forming with a hammer or an extrusion or casting, providing that measures are taken to minimize contamination from exposure to air. A meshed screen, such as a basket 32 is made of stainless steel mesh (or any other suitable material). The meshed screen 32 is positioned over the metal 30 and can be secured to the wall 16a of the tube 12 using a fastening means, such as for example a clamp, so that the basket 32 does not slide off the tube 12 during operation. The basket 32 can prevent the liquid metal (liquefied during heating phase) from dripping into the vessel. The meshed basket 32 is selected so that it can contain the metal in solid and/or liquid phase but will pass the metal vapors in the evaporation phase. For example, the aperture size of the mesh can be in a range of 0.1-1 mm so that the liquid metal will wet the basket's wall but will not drip out from the basket 32 into the vessel due to the surface tension at the meshed wall of the basket 32. Because of the high surface tension of liquid metal 30, liquid metal is contained by the meshed basket/screen 32 and evaporate in all direction in a line-of-sight of the screen 32 without dripping or spilling. In one implementation, instead of having a solid metal fitted to the wall 16a, chips of solid metal (e.g. chips of solid lithium metal) can be placed into the basket 32. When the heating device 20 is on, the metal is first liquefied wetting the basket 32 and then is vaporized. The metal vapors can travel to the vessel's inner surfaces that are in the line-of-sight (see radially dispersing arrows of FIG. 1) where in contact to a cooler surface of the vessel the metal solidifies forming a thin and uniform coating therein.

The device 10 of the present invention is orientation insensitive meaning that it can be operated in different orientations relative to gravity. For example, the device 10 can be inserted into the vessel so that the tube 12 is directed straight down from the vacuum flange or upward from the bottom of the vessel (vacuum flange can be added at the bottom of the vessel) or it can operate horizontally with the tube 12 extending sideways from the vacuum flange.

In one mode of operation, the device 10 is inserted into the vessel and is secured to the vessel wall 17. The vessel is then brought to a vacuum using a pumping system (not shown). The first end 14 of the tube 12 is then positioned at the desired depth into the vessel by lowering or raising the tube 12 using for example the bellows 18. The device 10 can be inserted into a top surface of the vessel so that it can coat straight down at the surrounding surfaces, however person skilled in the art would understand that it can be inserted into the vessel at any of its sides or surfaces without departing from the scope of the invention. During operation the heating device 20 is heated by turning on the power source 21. The temperature controller 22 that is in communication with the heating device's thermocouple can also be in communication with the power source 21. The controller 22 is programmed to keep the temperature of the heating device 20 at a pre-determined (target) value for desired time (coating period). The heat from the heating device 20 transfers across the wall 16a of the tube 12 into the metal 30. Because the heating is performed under vacuum the metal 30 can heat much quicker so the heater 20 can have a relatively low thermal output. For example, the heater 20 can be a cartridge heater with thermal output of 10-50 W in order to liquefy and evaporate about 0.5-5 g lithium. The tube 12 can be stainless steel with a wall thickness of about 0.5-1 mm. It can take about 5-10 min for the lithium to get heated to a target temperature of about 500° C. Heat transfer across the thin wall of stainless steel into the solid metal 30 can be effective despite the relatively low thermal conductivity of stainless steel by selecting a sufficiently small thickness of the wall 16a (thin wall) and providing a sufficiently large heating area. Temperature measurements taken during experiments conducted at General Fusion Inc., Burnaby, Canada, have shown that the temperature of the metal (e.g. lithium) in the metal piece 30 is within 1° C. of the temperature of the cartridge heater 20. However, heat transfer along the length of the tube 12 is much less, so that the connection (vacuum flange) at the vacuum wall 17 can be near room temperature, even with the heating device 20 at 500° C. When the temperature of the metal 30 (e.g. lithium) reaches melting point of the metal (around 200° C. for lithium), it starts melting into the basket 32, wetting it, but does not drip through the basket unless it is shaken or knocked. Once the temperature reaches evaporation point of the metal (around 450° C. for lithium), metal evaporation starts to occur.

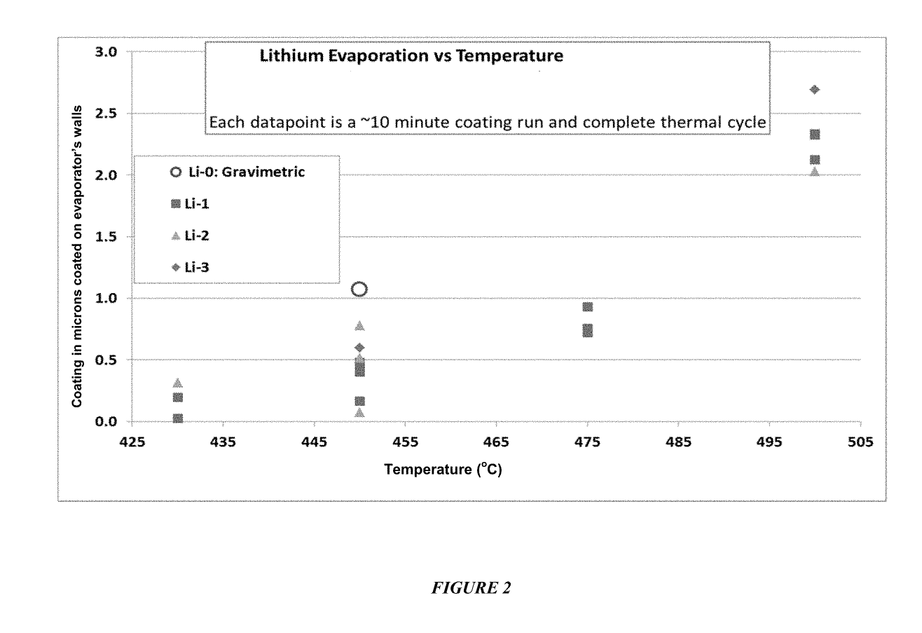

FIG. 2 illustrates data of lithium coating (in microns) at different temperatures (in ° C.) obtained for a 10 minute coating period and a complete thermal cycle. Four different devices 10 have been built, identified as Li-0, Li-1, Li-2 and Li-3, and used in the experiments. All four devices use same metal composition (lithium composition) and metal amount. Each datapoint is a 10 minute coating period from the time the heating device 20 reaches the desired (target) temperature. The complete thermal cycle includes the time from turning on the heater 20, reaching the target temperature, coating period at the target temperature and cooling down to room temperature. For example, the coating period can be 10 minutes, and the thermal cycle can be about 20-60 min for heating about 0.5-5 gr lithium to 500° C. target temperature and then cooling it down to ambient temperature (e.g. 25-30° C.). The amount of lithium coating was measured using two techniques: gravimetric analysis and non-gravimetric measurements by conductivity. The surfaces coated were washed with distilled and deionized water to dissolve all the deposited lithium, and then the conductivity of the resulting solution was measured. By comparing against control solutions containing known amounts of lithium, the amount of lithium deposited on the walls was determined. As can be noticed, the evaporation rate and the corresponding thickness of the deposited coat increases with the temperature, however the thickness of the lithium coating is also affected by a wetting stage of the basket 32 such as for example the amount of metal coating is reduced if the basket 32 is barely wetted comparing with cases when the device 10 was first heated so that the basket 32 can be fully wetted before operation. The experiments have shown that as the wetting of the basket 32 progresses, the thickness of the metal coating increases, for the same duration of a coating run. Therefore better results and more controllable thickness of the coating layer can be obtained if before operation the device 10 is first heated so that the basket 32 is fully wetted.

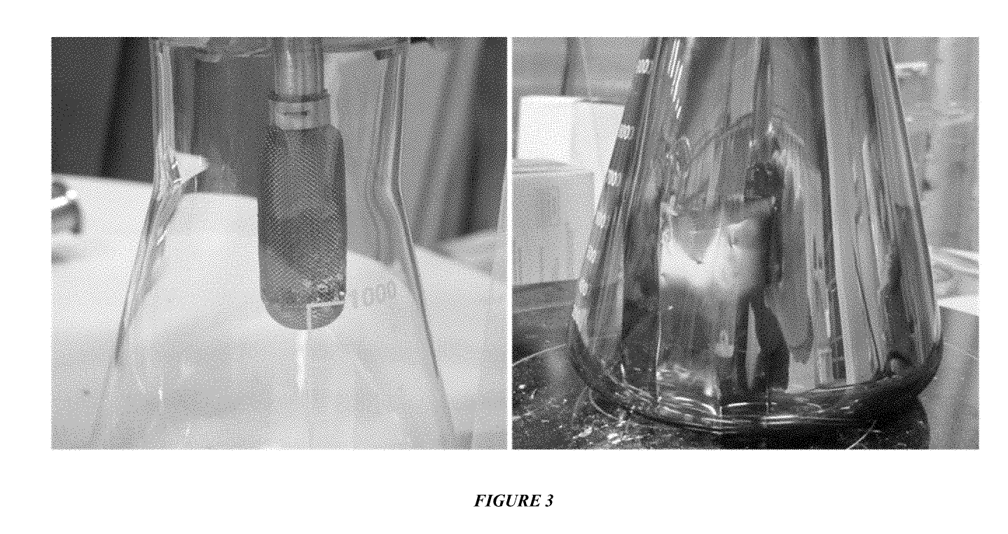

Uniformity of the lithium coating and evaporation of lithium is demonstrated by observing a surface of an evacuated flask containing the device 10 (FIG. 3). A left photo shows a clear flask and the device 10 with a tube 12 and the basket 32 placed at certain depth within the flask before the operation. A photo on the right shows the flask with coated inner surfaces after about a 10 minute coating period at about a 500° C. target temperature. As can be seen in FIG. 3, the lithium coating is uniformly dispersed on all surfaces in the line-of-sight of the basket 32. To confirm that the coating is uniform a number of same size stainless steel foils were placed around the device 10 in the flask. After the coating period the amount of lithium in each of the foils was measured confirming approximately the same amount of lithium deposited therein.

After the coating operation is completed, the metal (lithium) can be rapidly cooled by removing the heating device 20 from the tube 12 and purging a cooling gas into the tube's bottom. Additionally or alternately, a cooling gas can be purged through narrow gaps between the heating device 20 and the tube's inner wall. For example, the cooling gas can be a compressed air or compressed inert gas such as argon or helium. Depending on the temperature and flow rate of the gas the cooling period may vary. For example, if the gas is at room temperature (e.g. 20° C.) at 60 psi, due to a narrow passage between the heater 20 and the inner wall of the tube 12, the flow rate can be relatively low and the duration of the cooling period may be 30-40 min. However, if a cooled gas is used or higher flow rate is provided (heater is removed or gas at higher pressure is used) the cooling period can be shorten to about 5 min or less. The controller (same or separate from the controller 22) can be in communication with a cooling gas source and can be programmed to trigger injection of the cooling gas into the tube once the coating period is completed.

In one implementation, several coating operation can be performed in order to get the desired amount of metal coating or get coating at different positions. After each complete thermal cycle the used device 10 can be removed from the vessel and an unused (new) device 10 can be inserted and positioned in the vessel, and then the evaporation process can be repeated in a new thermal cycle. The removal of the used device and the insertion of the new (unused) device 10 can be done in an inert gas atmosphere such as for example helium or argon in order to minimize contamination of the metal 30 from exposure to air. After insertion of the new device 10 into the vessel, the pumping system is used to evacuate the vessel before the new evaporation cycle is triggered.

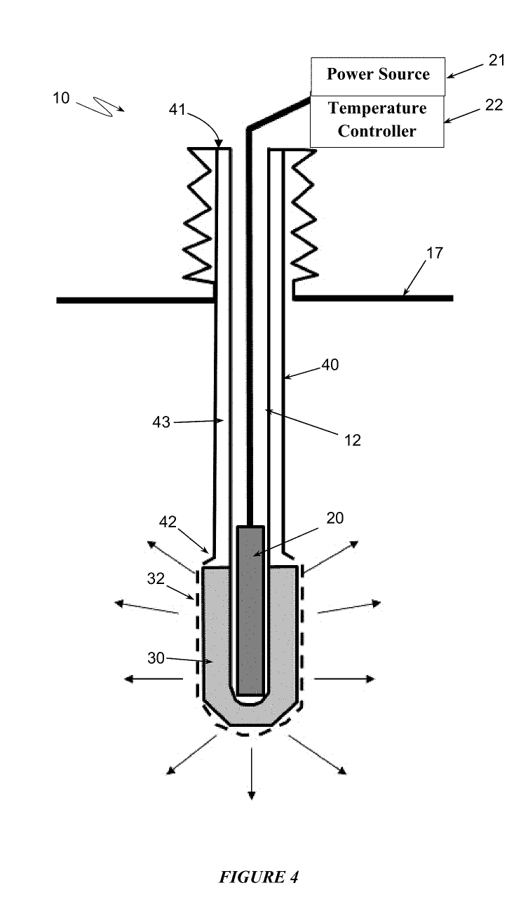

In one implementation, the amount of metal 30 in the device 10 can be rechargeable to provide additional metal for the new evaporation operation without removing the device 10 from the vacuum vessel. FIG. 4 shows the device 10 for evaporating metal further comprising a sleeve 40 that envelops the length of the tube 12. The sleeve 40 has a first open end 41 and a second end 42. The second end 42 is connected to the meshed basket 32. The sleeve 40 further comprises fastening means (not shown) to secure the sleeve 40 to the tube 12 so that the position of the sleeve in relation to the tube 12 is predetermined and fixed along the length of the sleeve such that the sleeve 40 is integral with the tube 12. For example a plurality of rigid arms (not shown) protruding of the inner surface of the sleeve 40 can be connected to the outer surface of the tube 12 to keep the sleeve 40 connected to the tube 12. A passage 43 is formed between the outside surface of the tube 12 and an inner surface of the sleeve 40. The solid metal 30 can be inserted into the meshed basket 32 through the opened end 41 and the passage 43. During the evaporation process the open end 41 of the sleeve 40 is sealed with a suitable vacuum seal. When additional amount of metal is required for continuing evaporation operation or a sequential new coating operation, a new metal piece(s) is inserted through the passage 43 into the meshed basket 32. The recharge of the new metal 30 is performed in an inert gas atmosphere and then a vacuum is established using a pumping system (not shown).

The device 10 of the present embodiments is orientation insensitive. For example, the metal 30 can be inserted through the passage 43 using a pusher such as a spring (not shown) in case the device 10 is positioned in horizontal direction or upward from the bottom of the vessel. Metal dripping and/or spilling is prevented by avoiding any free surface of metal. When inserted, the metal is in a solid form at room temperature thus avoiding any safety hazards associated with metal nanopowder. Heating and temperature control of the metal is done entirely outside the vacuum vessel, so that all parts of the heating subsystem can be serviced and replaced without breaking the vacuum.

In addition to using the device 10 for gettering and surface conditioning it can also be used for creating metal alloys e.g. lead-lithium eutectic alloys. In the process of mixing lead and lithium, it is sometimes important to avoid regions of high Li concentration, to avoid formation of high melting point compounds or Li aggregation. Evaporation of lithium onto a mass of molten lead may provide a means to mix the lithium into the lead in a very controlled manner. In order to obtain the required homogeneity and controlled ratio of metals into the metal mixture, a second metal is put into a vessel, such as the vacuum vessel of FIG. 1. The second metal can be a liquid phase metal such as a liquid phase lead, or the metal can be sequentially liquefied by heating and melting the second metal. A device 10 containing a select first metal in solid phase (e.g. solid lithium) can be then inserted into the vessel (in an inert gas atmosphere) and the vessel can be evacuated using a pumping system. The first and the second metals (i.e. lithium and lead) can be at least 99% by mass pure. In order to obtain the lead-lithium eutectic alloy, the lead in the vessel is stirred and the temperature is brought higher of the melting point of the first and second metals (depending on the melting point of a composition). Then the device 10 is triggered as described herein to vaporize the first metal, and a vapor of the first metal (e.g. lithium) is applied to the second metal and mixed therein in a controlled manner until the desired chemical composition of the alloy is obtained. For example, the amount of Li into the lead lithium alloy can be in a range of 15.7-17 at. %. A person skilled in the art would understand that the device 10 can be used in production of any other metal alloys or any other chemical composition of such metal alloy without departing from the scope of the invention.

While particular elements, embodiments and applications of the present disclosure have been shown and described, it will be understood, that the scope of the disclosure is not limited thereto, since modifications can be made without departing from the scope of the present disclosure, particularly in light of the foregoing teachings. Thus, for example, in any method or process disclosed herein, the acts or operations making up the method/process may be performed in any suitable sequence and are not necessarily limited to any particular disclosed sequence. Elements and components can be configured or arranged differently, combined, and/or eliminated in various embodiments. The various features and processes described above may be used independently of one another, or may be combined in various ways. All possible combinations and sub-combinations are intended to fall within the scope of this disclosure. Reference throughout this disclosure to “some embodiments,” “an embodiment,” or the like, means that a particular feature, structure, step, process, or characteristic described in connection with the embodiment is included in at least one embodiment. Thus, appearances of the phrases “in some embodiments,” “in an embodiment,” or the like, throughout this disclosure are not necessarily all referring to the same embodiment and may refer to one or more of the same or different embodiments. Indeed, the novel methods and systems described herein may be embodied in a variety of other forms; furthermore, various omissions, additions, substitutions, equivalents, rearrangements, and changes in the form of the embodiments described herein may be made without departing from the spirit of the inventions described herein.

Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without operator input or prompting, whether these features, elements and/or steps are included or are to be performed in any particular embodiment. No single feature or group of features is required for or indispensable to any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Conjunctive language such as the phrase “at least one of X, Y and Z,” unless specifically stated otherwise, is otherwise understood with the context as used in general to convey that an item, term, etc. may be either X, Y or Z. Thus, such conjunctive language is not generally intended to imply that certain embodiments require at least one of X, at least one of Y and at least one of Z to each be present.

The example calculations, simulations, results, graphs, values, and parameters of the embodiments described herein are intended to illustrate and not to limit the disclosed embodiments. Other embodiments can be configured and/or operated differently than the illustrative examples described herein. The scope of the claims should not be limited by the preferred embodiments set forth in the examples, but should be given the broadest interpretation consistent with the description as a whole.

What is claimed is:

1. A device for evaporating a solid phase select metal in a vacuum, the device comprising:
a tube having a closed first end, a second end and a body extending between the first end and the second end, the body having a wall defining an inner cavity of the tube;
a heating device electrically connectable to a power source, the heating device comprising a heater positioned inside the inner cavity of the tube and in thermal communication with the wall of the tube body;
a meshed screen mounted on an outside surface of the tube and defining a basket for containing the solid phase select metal and positioning the select metal in thermal communication with the wall of the tube body, the meshed screen having a screen aperture size sufficient to contain the select metal when in liquid or solid phases and to pass the select metal when in vapor phase; and,
wherein the heater output, tube wall thermal conductivity, and heater and metal positions are selected such that heat from the heater is sufficient to liquefy and then vaporize the select metal.

2. The device of claim 1 further comprising a vessel seal surrounding the tube body and configured to sealably connect the device to a vacuum vessel such that the first end of the tube and meshed screen are positionable inside the vessel, and the heater is operable to liquefy and then vaporize the select metal inside the vessel such that the select metal coats inner surfaces of the vessel in line of sight with the meshed screen.

3. The device of claim 1, wherein the select metal comprises a plurality of metal chips.

4. The device of claim 2, wherein the vessel seal further comprises means for moving the device within the vessel while maintaining a vacuum seal.

5. The device of claim 1, wherein the heating device further comprises a sensor for measuring temperature of the heater and a controller in communication with the sensor and communicable with the power source, the controller programmed to control the temperature of the heater at a pre-determined target temperature for a pre-determined coating time.

6. The device of claim 5, further comprising cooling means in thermal communication with the heater, the controller being configured to trigger the cooling means to cool the heater.

7. The device of claim 1, further comprising a sleeve enveloping the tube, the sleeve having a first open end and a second end, the second end of the sleeve connected to the meshed screen, wherein a passage is formed between the outside surface of the tube and an inner surface of the sleeve.

8. The device of claim 1, wherein the tube is made of a stainless steel, and the wall of the tube has a thickness selected to provide the selected thermal conductivity.

9. The device of claim 1, wherein the select metal comprises lithium.

10. A method for evaporating a solid phase select metal in a vacuum, comprising:
(a) placing the solid phase select metal in a basket defined by a mesh screen mounted to an outside surface of a tube, and positioning the select metal in a vacuum and in thermal communication with a heater positioned inside the tube, wherein the mesh screen has an aperture size selected to contain the select metal when in liquid and solid phases, and to pass the select metal when in vapor phase; and
(b) operating the heater to generate a selected thermal output sufficient to liquefy then vaporize the select metal such that a vapor phase of the select metal passes through the mesh screen,
wherein the mesh screen, tube and heater are part of a device for evaporating the solid phase select metal.

11. The method as claimed in claim 10 further comprising placing the tube, mesh screen basket and solid phase select metal inside a vacuum vessel, and establishing a vacuum inside the vessel such that the vapor phase select material passing through the mesh screen will coat inner surfaces of the vacuum vessel that are in line of sight of the mesh screen basket.

12. The method as claimed in claim 11 further comprising:
adjusting a position of the device at a pre-determined depth and orientation in the vessel;
turning on a power source electrically connected to the heater and setting a temperature of the heater to a pre-determined target temperature and maintaining the temperature of the heater at such target temperature for a duration of a pre-determined coating period, the target temperature being higher than an evaporation point of the select metal;
melting the select metal into the meshed screen to wet the screen; and
dispersing vapors of the select metal on inner walls of the cavity that are in a line-of-sight of the meshed screen.

13. The method of claim 12, further comprising cooling the select metal down to ambient temperature.

14. The method of claim 11, wherein the device is placed in an orientation direction within the vacuum vessel differs from a direction of a gravitational force.

15. The method of claim 10, further comprising after (b) recharging the solid phase select metal by feeding additional solid phase select metal through a passage formed between the outside surface of the tube and an inner surface of a sleeve, wherein the sleeve envelopes the tube along its length, and a second end of the sleeve is connected to the mesh screen.

16. The method of claim 10, wherein the solid phase select metal comprises lithium.

17. The method as claimed in claim 10 further comprising liquefying a second metal, and contacting the vapor phase select metal with the liquefied second metal such that the select metal and second metal are mixed and a metal alloy is formed.

18. The method as claimed in claim 16 wherein the select metal comprises lithium and the second metal comprises lead.
